(19) United States
(12) Patent Application Publication
(10) Pub. No.: US 2025/0378892 A1
(43) Pub. Date: Dec. 11, 2025

(54) MEMORY SYSTEM AND OPERATION METHOD THEREOF

(71) Applicant: Yangtze Memory Technologies Co., Ltd., Wuhan (CN)

(72) Inventors: Tao XIONG, Wuhan (CN); Ao HUANG, Wuhan (CN)

(21) Appl. No.: 18/791,410

(22) Filed: Jul. 31, 2024

(30) Foreign Application Priority Data
Jun. 11, 2024 (CN) 202410749215.7

(51) Int. Cl. G11C 16/34; G11C 16/32

(52) U.S. Cl. CPC G11C 16/3418; G11C 16/32

(57) ABSTRACT

Methods, devices, and systems for managing memory devices are provided. In one aspect, a memory system can include a memory device including memory cells and a memory controller coupled to the memory device. The memory controller is configured to identify a current temperature of the memory system, determine a delay using fuzzy logic based on the current temperature; and control the memory device to execute an operation after the delay.

### CROSS-REFERENCE TO RELATED APPLICATIONS

This application claims priority to Chinese Patent Application No. 202410749215.7, filed on Jun. 11, 2024, which is hereby incorporated by reference in its entirety.

### TECHNICAL FIELD

The present disclosure generally relates to memory devices and memory systems, and in particular, to managing temperature in memory systems.

### BACKGROUND

Flash memory is a low-cost, high-density, nonvolatile solid-state storage medium that can be electrically erased and reprogrammed. Flash memory includes NOR flash memory and NAND flash memory. Various operations can be performed by a flash memory, for example, program (write) or read operations. Operations performed by a flash memory can affect temperature of the flash memory.

### SUMMARY

The present disclosure involves methods, apparatuses, and systems for managing temperature in a memory system. In one example, a memory system can include a memory device including memory cells and a memory controller coupled to the memory device. The memory controller is configured to identify a current temperature of the memory system, determine a delay using fuzzy logic based on the current temperature, and control the memory device to execute an operation after the delay. In some implementations, by implementing the delay, the temperature in the memory system can be lowered or otherwise controlled.

In some implementations, the memory controller is configured to identify the current temperature of the memory system by operations including receiving a first temperature from a first sensor positioned in the memory device, receiving a second temperature from a second sensor positioned in the memory controller, and determining the current temperature of the memory system based on at least one of the first temperature or the second temperature.

In some implementations, the current temperature is determined as a weighted average of the first temperature and the second temperature.

In some implementations, the memory controller receives the first temperature and the second temperature periodically.

In some implementations, the memory controller is configured to determine the delay using fuzzy logic by operations including fuzzifying a first difference between the current temperature and a previous temperature of the memory system into first membership values of the first difference with respect to first fuzzy sets that the first difference falls into, fuzzifying a second difference between the current temperature and a target temperature into second membership values of the second difference with respect to second fuzzy sets that the second difference falls into, mapping the first fuzzy sets and the second fuzzy sets into third fuzzy sets that indicate candidate delay changes, determining third membership values of the candidate delay changes with respect to third fuzzy sets based on the first membership values and the second membership values, and determining a target delay change by de-fuzzifying the candidate delay changes. The delay is a sum of a previous delay determined by the memory controller and the target delay change.

In some implementations, determining the target delay change by de-fuzzifying the candidate delay changes includes determining the target delay change based on the candidate delay changes indicated by the third fuzzy sets and the third membership values of the candidate delay changes with respect to the third fuzzy sets.

In some implementations, the second difference is less than 2 degree Celsius.

In some implementations, the operation to be executed after the delay includes one of a read operation, a write operation or an erase operation.

In some implementation, the memory controller is configured to control the memory device to execute the operation after the delay by operations including executing, by a processor of the memory controller, one or more No-Operation (NOP) commands. A quantity of the NOP commands is correlated with the delay.

In some implementations, the delay is stored in a storage medium of the memory controller, and a processor of the memory controller is configured to read the delay from the storage medium to control the memory device to execute the operation after the delay.

One aspect of the present disclosure features a memory controller including a temperature sampling circuit configured to identify a current temperature of a memory system including a memory device and the memory controller. The memory controller further includes a first processor configured to determine a delay using fuzzy logic based on the current temperature, and a second processor configured to control a memory device to execute an operation after the delay.

In some implementations, the temperature sampling circuit is configured to identify the current temperature of the memory system by operations including receiving a first temperature from a first sensor positioned in the memory device, receiving a second temperature from a second sensor positioned in the memory controller, and determining the current temperature of the memory system based on at least one of the first temperature or the second temperature.

In some implementations, the first processor is configured to determine the delay using fuzzy logic by operations including fuzzifying a first difference between the current temperature and a previous temperature of the memory system into first membership values of the first difference with respect to first fuzzy sets that the first difference falls into, fuzzifying a second difference between the current temperature and a target temperature into second membership values of the second difference with respect to second fuzzy sets that the second difference falls into, mapping the first fuzzy sets and the second fuzzy sets into third fuzzy sets that indicate candidate delay changes, determining third membership values of the candidate delay changes with respect to third fuzzy sets based on the first membership values and the second membership values, and determining a target delay change by de-fuzzifying the candidate delay changes, wherein the delay is a sum of a previous delay determined by the memory controller and the target delay change.

In some implementations, determining the target delay change by de-fuzzifying the candidate delay changes includes determining the target delay change based on the candidate delay changes indicated by the third fuzzy sets and the third membership values of the candidate delay changes with respect to third fuzzy sets.

In some implementations, the second processor is configured to control the memory device to execute the operation after the delay by operations including executing, by a processor of the memory controller, one or more No-Operation (NOP) commands. A quantity of the NOP commands is correlated with the delay.

In some implementations, the delay is stored in a storage medium of the memory controller, and the second processor is configured to read the delay from the storage medium to control the memory device to execute the operation after the delay.

One aspect of the present disclosure features a method of controlling a memory system. The method includes identifying a current temperature of the memory system including a memory controller and a memory device, determining a delay using fuzzy logic based on the current temperature, and controlling the memory device to execute an operation after the delay.

In some implementations, determining the delay using fuzzy logic by operations include fuzzifying a first difference between the current temperature and a previous temperature of the memory system into first membership values of the first difference with respect to first fuzzy sets that the first difference falls into, fuzzifying a second difference between the current temperature and a target temperature into second membership values of the second difference with respect to second fuzzy sets that the second difference falls into, mapping the first fuzzy sets and the second fuzzy sets into third fuzzy sets that indicate candidate delay changes, determining third membership values of the candidate delay changes with respect to third fuzzy sets based on the first membership values and the second membership values, and determining a target delay change by de-fuzzifying the candidate delay changes, wherein the delay is a sum of a previous delay determined by the memory controller and the target delay change.

In some implementations, the method further includes controlling the memory device to execute the operation after the delay includes executing, by a processor of the memory controller, one or more No-Operation (NOP) commands, wherein a quantity of the NOP commands is correlated with the delay.

In some implementations, the method further includes storing the delay in a storage medium of the memory controller, and reading, by a processor of the memory controller, the delay from the storage medium to control the memory device to execute the operation after the delay.

One aspect of the present disclosure features a non-transitory, computer readable medium. The non-transitory, computer readable medium stores one or more instructions executable by a memory system to perform operations including: identifying a current temperature of the memory system comprising a memory controller and a memory device, determining a delay using fuzzy logic based on the current temperature, and controlling the memory device to execute an operation after the delay.

While generally described as computer-implemented software embodied on tangible media that processes and transforms the respective data, some or all of the aspects may be computer-implemented methods or further included in respective systems or other devices for performing this described functionality. The details of these and other aspects and implementations of the present disclosure are set forth in the accompanying drawings and the description below. Other features, objects, and advantages of the disclosure will be apparent from the description and drawings, and from the claims.

### BRIEF DESCRIPTION OF DRAWINGS

FIG. 1 illustrates a block diagram of an example system having a memory device, according to some aspects of the present disclosure.

FIGS. 2A-2B illustrate example storage products, according to some aspects of the present disclosure.

FIG. 3 illustrates an example of a schematic diagram of a memory device including peripheral circuits, according to some aspects of the present disclosure.

FIG. 4 illustrates some example peripheral circuits, according to some aspects of the present disclosure.

FIG. 5 illustrates a block diagram of an example system including a memory device, a memory controller and temperature sensors, according to some aspects of the present disclosure.

FIG. 6 illustrates an example method of controlling temperature using fuzzy logic, according to some aspects of the present disclosure.

FIG. 7A illustrates an example mapping table that maps a first temperature difference to first fuzzy sets, according to some aspects of the present disclosure.

FIG. 7B illustrates an example membership function that determines first membership values of the first temperature difference with respect to the first fuzzy sets, according to some aspects of the present disclosure.

FIG. 8A illustrates an example mapping table that maps a second temperature difference to second fuzzy sets, according to some aspects of the present disclosure.

FIG. 8B illustrates an example membership function that determines second membership values of the second temperature difference with respect to the second fuzzy sets, according to some aspects of the present disclosure.

FIG. 9 illustrates an example look-up table that maps the first fuzzy sets and the second fuzzy sets to third fuzzy sets, according to some aspects of the present disclosure.

FIG. 10A illustrates an example mapping table that maps third fuzzy sets to candidate delay changes, according to some aspects of the present disclosure.

FIG. 10B illustrates an example membership function that determines a target delay change based on membership values of the candidate delay changes with respect to the third fuzzy sets, according to some aspects of the present disclosure.

FIG. 11 illustrates performances of a memory device where temperature is controlled using a Proportional-Integral-Derivative (PID) mechanism.

FIG. 12 illustrates performances of a memory device where temperature is controlled using fuzzy logic, according to some aspects of the present disclosure.

FIG. 13 illustrates a flow chart of an example method of operating a memory system, according to some aspects of the present disclosure.

Like reference numbers and designations in the various drawings indicate like elements.

### DETAILED DESCRIPTION

This specification relates to memory devices, memory systems, and methods for managing temperature in a memory system (e.g., a solid-state drive, SSD). In some applications, as the performance of a memory system continues to enhance, the increase of power consumption leads to a growing demand for effective temperature control. Effective temperature control can enhance the performance of the memory system, while ensuring that the temperature does not exceed a safety threshold and preventing hardware damage.

Methods to manage the temperature in the memory system can include a simple feedback control and Proportional-Integral-Derivative (PID) control, among others. As one example, the simple feedback control turns on/off thermal throttling mechanisms by comparing the current temperature of the memory system to a threshold temperature. The thermal throttling mechanisms are turned on when the current temperature exceeds the threshold temperature. In some cases, the simple feedback control cannot keep the temperature at a stable level, and may lead to temperature overshooting (e.g., temperature rising to an unexpected high value) As another example, the PID control adjusts the thermal throttling mechanism (e.g., by adjusting the length of a delay before an upcoming operation of the memory device, or by adjusting the power of the control logic of the memory device) in consideration of a current temperature error, a cumulative temperature error, and a current rate of change of the temperature error. In some cases, the PID control cannot control the temperature of the memory system precisely, and can lead to excessive performance loss of the memory device. In addition, due to the nonlinear and hysteretic nature of temperature changes, it is difficult to find PID parameters that are universally applicable for different memory systems and for various cooling conditions (such as ambient temperature, heat sink, and fan airflow).

The present disclosure provides techniques to manage the temperature of a memory system using fuzzy logic. In some implementations, a memory controller of the memory system can determine a delay based on the current temperature of the memory system, according to pre-set fuzzy rules. The memory controller can further control the memory device to execute an upcoming operation after the delay, so that heat generation can be delayed or reduced. In some implementations, the memory controller can fuzzify a first input (e.g., a first temperature difference between the current temperature and a target temperature) and a second input (e.g., a second temperature difference between the current temperature and a previous temperature). After making inferences on the delay based on the pre-set fuzzy rules, the memory controller can determine a de-fuzzified value for the delay.

In some implementations, the described techniques can achieve one or more technical effects. For example, the described techniques can manage the temperature of the memory system more precisely, keep the temperature stably under a threshold, and reduce or prevent temperature over-shooting. As another example, temperature control using fuzzy logic can be broadly applicable across different memory systems, under different host workload, and under varying cooling conditions. In some implementations, the described techniques do not require tuning parameters for different devices or different operation conditions. In addition, the described techniques can be easily implemented, for example, in the firmware of the memory controller, without needing to change hardware structures of the memory controller or the memory system. In some implementations, additional or different technical effects can be achieved.

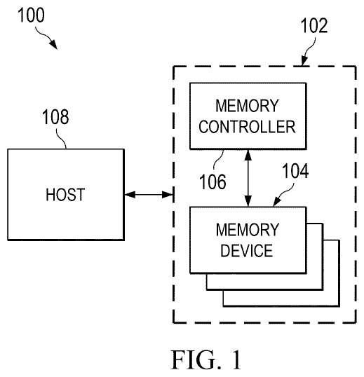

FIG. 1 illustrates a block diagram of an example system 100 having a memory device, according to some aspects of the present disclosure. The system 100 can be a mobile phone, a desktop computer, a laptop computer, a tablet, a vehicle computer, a gaming console, a printer, a positioning device, a wearable electronic device, a smart sensor, a virtual reality (VR) device, an argument reality (AR) device, or any other suitable electronic devices having storage therein. As shown in FIG. 1, the system 100 can include a host 108 and a memory system 102 having one or more memory devices 104 and a memory controller 106. The host 108 can include one or more processors of an electronic device. The processor can be a central processing unit (CPU), or a system-on-chip (SoC), such as an application processor (AP). The host 108 can be configured to send or receive data and commands to or from the memory systems 102.

The memory device 104 can be any memory device disclosed in the present disclosure, such as a NAND Flash memory device. It is noted that the NAND Flash is only one example of memory device for illustrative purposes. It can include any suitable solid-state, non-volatile memory, e.g., NOR Flash, Ferroelectric RAM (FeRAM), Phase-change memory (PCM), Magne-to-resistive random-access memory (MRAM), Spin-transfer torque magnetic random-access memory (STT-RAM), or Resistive random-access memory (RRAM), etc. In some implementations, memory device 104 includes a three-dimensional (3D) NAND Flash memory device.

The memory controller 106 can be implemented by microprocessors, microcontrollers (a.k.a. microcontroller units (MCUs)), digital signal processors (DSPs), application-specific integrated circuits (ASICs), field-programmable gate arrays (FPGAs), programmable logic devices (PLDs), state machines, gated logic, discrete hardware circuits, and other suitable hardware, firmware, and/or software configured to perform the various functions described below in detail.

The memory controller 106 is coupled to the memory device 104 and to the host 108, and is configured to control the memory device 104, according to some implementations. The memory controller 106 can manage the data stored in the memory device 104 and can communicate with the host 108. In some implementations, the memory controller 106 is designed for operating in a low duty-cycle environment, such as secure digital (SD) cards, compact Flash (CF) cards, universal serial bus (USB) Flash drives, or other media for use in electronic devices, such as personal computers, digital cameras, mobile phones, etc. In some implementations, memory controller 106 is designed for operating in a high duty-cycle environment solid state drives (SSDs) or embedded multi-media-cards (eMMCs) used as data storage for mobile devices, such as smartphones, tablets, laptop computers, etc., and enterprise storage arrays. The memory controller 106 can be configured to control operations of the memory device 104, such as read, erase, and program operations. The memory controller 106 can also be configured to manage various functions with respect to the data stored or to be stored in the memory device 104 including, but not limited to bad-block management, garbage collection, logical-to-physical address conversion, logical-to-physical mapping management, wear leveling, etc. In some implementations, the memory controller 106 is further configured to process error correction codes (ECCs) with respect to the data read from or written to the memory device 104. Any other suitable functions can be performed by the memory controller 106 as well, for example, formatting the memory device 104.

The memory controller 106 can communicate with an external device (e.g., the host 108) according to a particular communication protocol. For example, the memory controller 106 can communicate with the external device through at least one of various interface protocols, such as a USB protocol, an MMC protocol, a peripheral component interconnection (PCI) protocol, a PCI-express (PCI-E) protocol, an advanced technology attachment (ATA) protocol, a serial-ATA protocol, a parallel-ATA protocol, a small computer small interface (SCSI) protocol, an enhanced small disk interface (ESDI) protocol, an integrated drive electronics (IDE) protocol, a Firewire protocol, etc. The memory controller 106 is configured to receive and transmit a command to and from the host 108, and execute or perform multiple functions and operations provided in the present disclosure, which will be described later.

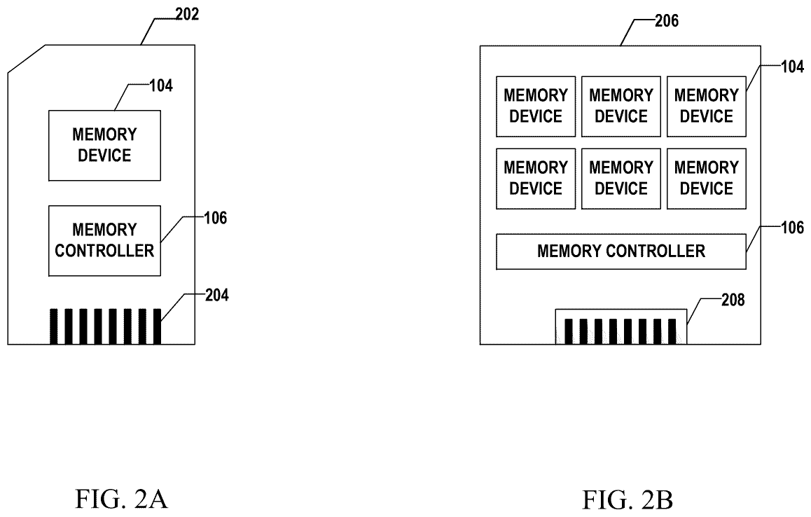

The memory controller 106 and the one or more memory devices 104 can be integrated into various types of storage devices. For example, the memory controller 106 and the one or more memory devices 104 can be packaged in a universal Flash storage (UFS) package or an eMMC package. In one example as shown in FIG. 2A, the memory controller 106 and a single memory device 104 can be integrated into a memory card 202. The memory card 202 can include a PC card (PCMCIA, personal computer memory card international association), a CF card, a smart media (SM) card, a memory stick, a multimedia card (MMC, RS-MMC, MMCmicro), an SD card (SD, miniSD, microSD, SDHC), a UFS, etc. The memory card 202 can further include a memory card connector 204 coupling the memory card 202 with a host (e.g., host 108 in FIG. 1). In another example as shown in FIG. 2B, the memory controller 106 and multiple memory devices 104 can be integrated into an SSD 206. The SSD 206 can further include an SSD connector 208 that couples the SSD 206 with a host (e.g., host 108 in FIG. 1). In some implementations, the storage capacity and/or the operation speed of the SSD 206 is greater than those of the memory card 202.

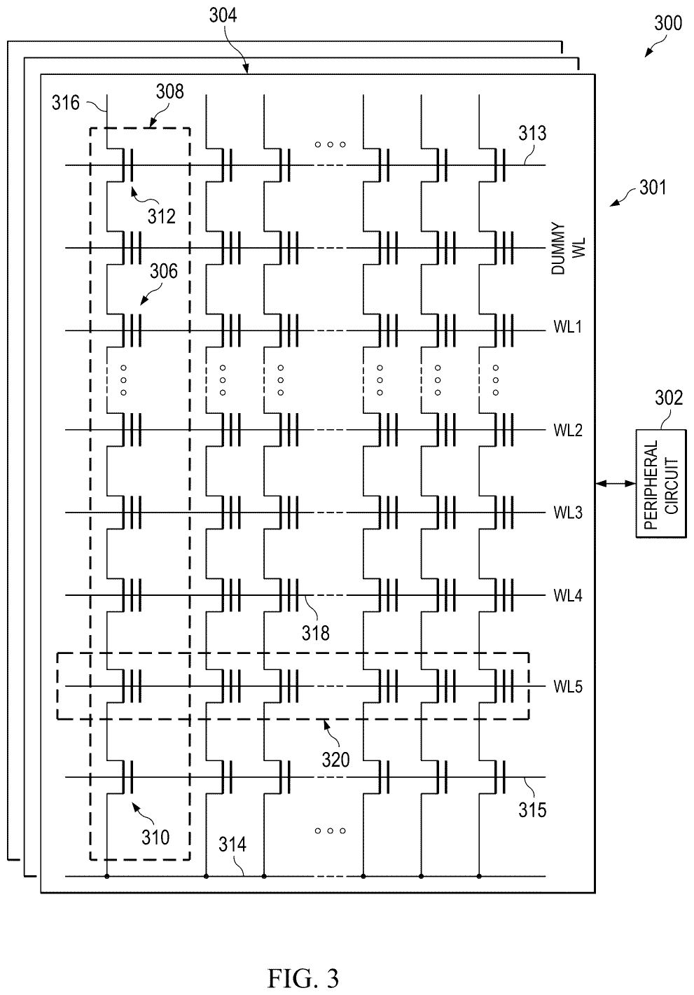

FIG. 3 illustrates an example of a schematic diagram of a memory device 300 including peripheral circuits, according to some aspects of the present disclosure. The memory device 300 can include a memory cell array 301 and peripheral circuits 302 coupled to the memory cell array 301. The memory cell array 301 can be a NAND Flash memory cell array in which memory cells 306 are provided in the form of an array of NAND memory strings 308 each extending vertically above a substrate (not shown in FIG. 3). In some implementations, each NAND memory string 308 includes a plurality of memory cells 306 coupled in series and stacked vertically. Each memory cell 306 can hold a continuous, analog value, such as an electrical voltage or charge that depends on the number of electrons trapped within a storage layer of the memory cell 306. The logic state (i.e., data) of each memory cell 306 in a memory block 304 can be determined based on the threshold voltage Vth of the memory cell 306. Each memory cell 306 can be a floating gate type memory cell including a floating-gate transistor, or a charge trap type memory cell including a charge-trap transistor.

In some implementations, each memory cell 306 is a single-level cell (SLC) with two possible memory states that can store one bit of data. For example, the first memory state “0” can correspond to a first range of voltages, and the second memory state “1” can correspond to a second range of voltages. In some implementations, each memory cell 306 is a multi-level cell (MLC) that is capable of storing more than one bit of data in more than two memory states. For example, the MLC can store two bits per cell, three bits per cell (also known as triple-level cell (TLC)), or four bits per cell (also known as a quad-level cell (QLC)). Each MLC can be programmed to support a range of possible nominal storage values. In one example, if each MLC stores two bits of data, then the MLC can be programmed to one of three possible programming levels from an erased state by writing one of three possible nominal storage values to the cell. A fourth nominal storage value can be used for the erased state.

As shown in FIG. 3, each NAND memory string 308 can include a source select gate (SSG) 310 at its source end and a drain select gate (DSG) 312 at its drain end. The SSG 310 and the DSG 312 can be configured to activate selected NAND memory strings 308 (columns of the array) during read and program operations. In some implementations, the sources of NAND memory strings 308 in the same memory block 304 are coupled through a same source line (SL) 314, e.g., a common SL. In other words, NAND memory strings 308 in the same memory block 304 have an array common source (ACS), according to some implementations. The DSG 312 of each NAND memory string 308 is coupled to a respective bit line 316 from which data can be read or written via an output bus (not shown), according to some implementations. In some implementations, each NAND memory string 308 is configured to be selected or deselected by applying a select voltage (e.g., above the threshold voltage of the transistor having the DSG 312) or a deselect voltage (e.g., 0 V) to the respective DSG 312 through one or more DSG lines 313, and/or by applying a select voltage (e.g., above the threshold voltage of the transistor having the SSG 310) or a deselect voltage (e.g., 0 V) to the respective SSG 310 through one or more SSG lines 315.

As shown in FIG. 3, NAND memory strings 308 can be organized into multiple memory blocks 304, each of which can have a common SL 314 coupled to the ACS. In some implementations, each memory block 304 can serve as a basic data unit for erase operations, such that memory cells 306 on the same memory block 304 are erased at the same time. To erase memory cells 306 in a selected memory block 304, the SL 314 coupled to the selected memory block 304 and unselected memory blocks in the same plane can be biased with an erase voltage. For example, the erase voltage can be a high positive voltage (e.g., 20 V or more). In some implementations, an erase operation can be performed at a half-block level, a quarter-block level, or a level having any suitable number of memory blocks or fractions of a memory block.

The memory cells 306 of adjacent NAND memory strings 308 can be coupled through word lines 318. The word line 318 can select which row of memory cells 306 is affected by read and program operations. Each word line 318 can include a gate line coupled to a plurality of control gates (gate electrodes) of a plurality of memory cells 306. Example word lines shown in FIG. 3 are between one or more DSG lines 313 and one or more SSG lines 315.

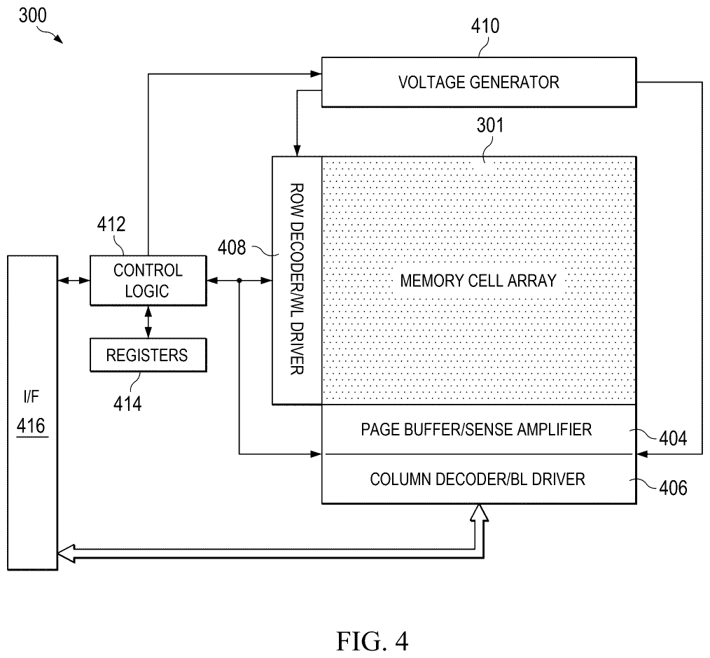

FIG. 4 illustrates some example peripheral circuits 302, according to some aspects of the present disclosure. The peripheral circuits 302 can be coupled to the memory cell array 301 through bit lines 316, word lines 318, SLs 314, SSG lines 315, and DSG lines 313. The peripheral circuits 302 can include any suitable analog, digital, and mixed-signal circuits for facilitating the operations of the memory cell array 301 by applying and sensing voltage signals and/or current signals to and from each target memory cell 306 through bit lines 316, word lines 318, SLs 314, SSG lines 315, and DSG lines 313. The peripheral circuits 302 can include various types of peripheral circuits formed using metal-oxide-semiconductor (MOS) technologies. The example peripheral circuits 302 include a page buffer/sense amplifier 404, a column decoder/bit line driver 406, a row decoder/word line driver 408, a voltage generator 410, control logic 412, registers 414, an interface 416, and a data bus. In some examples, additional peripheral circuits not shown in FIG. 4 may be included as well.

The page buffer/sense amplifier 404 can be configured to read and program (write) data from and to memory cell array 301 according to the control signals from control logic 412. In an example, the page buffer/sense amplifier 404 may store one page of program data (write data) to be programmed into one page 320 of the memory cell array 301. In another example, the page buffer/sense amplifier 404 may perform program verify operations to ensure that the data have been properly programmed into memory cells 306 coupled to selected word lines 418. In still another example, the page buffer/sense amplifier 404 may also sense the low power signals from the bit line 316 that represents a data bit stored in memory cell 306, and amplify the small voltage swing to recognizable logic levels in a read operation. The column decoder/bit line driver 406 can be configured to be controlled by the control logic 412 and select one or more NAND memory strings 308 by applying bit line voltages generated from the voltage generator 410.

The row decoder/word line driver 408 can be configured to be controlled by the control logic 412 and select/deselect memory blocks 304 of the memory cell array 301 and select/deselect word lines 418 of the memory block 304. The row decoder/word line driver 408 can be further configured to drive word lines 418 using word line voltages generated from the voltage generator 410. In some implementations, the row decoder/word line driver 408 can also select/deselect and drive SSG lines 415 and DSG lines 413. As described below in detail, the row decoder/word line driver 408 is configured to apply a program voltage to selected word line 418 in a program operation on memory cell 306 coupled to selected word line 418.

The voltage generator 410 can be configured to be controlled by the control logic 412 and generate the word line voltages (e.g., read voltage, program voltage, pass voltage, local voltage, verify voltage, etc.), bit line voltages, and source line voltages to be supplied to the memory cell array 301.

The control logic 412 can be coupled to each peripheral circuit described above and configured to control operations of each peripheral circuit. The registers 414 can be coupled to the control logic 412 and include status registers, command registers, and address registers for storing status information, command operation codes (OP codes), and command addresses for controlling the operations of each peripheral circuit.

The interface 416 can be coupled to the control logic 412 and act as a control buffer to buffer and relay control commands received from a host (not shown) to the control logic 412 and status information received from the control logic 412 to the host. The interface 416 can also be coupled to the column decoder/bit line driver 406 via a data bus, and act as a data input/output (I/O) interface and a data buffer to buffer and relay data to and from the memory cell array 301.

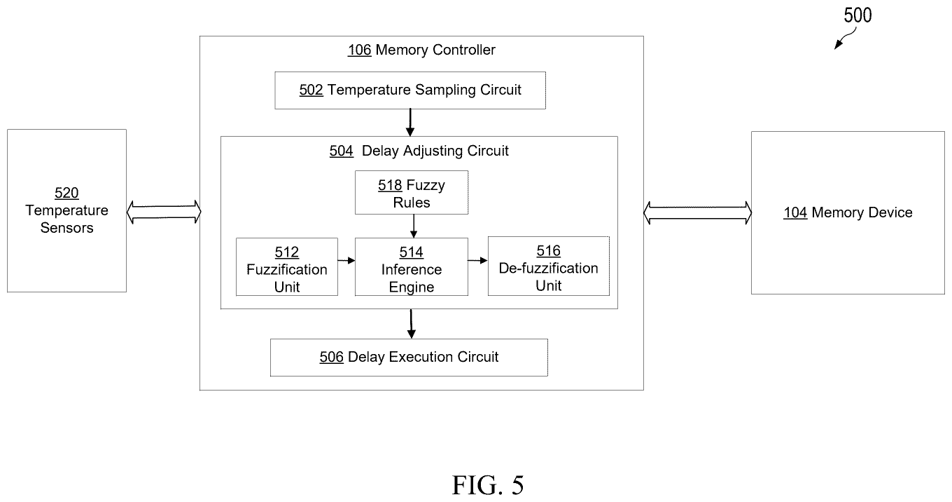

FIG. 5 illustrates a block diagram of an example system 500 including a memory device 104, a memory controller 106, and temperature sensors 520, according to some aspects of the present disclosure. In some implementations, the temperature sensors 520 can include a plurality of sensors positioned separately on the memory device 104 and the memory controller 106. For example, some temperature sensors 520 can sense the temperature of one or more parts of the memory device 104 (e.g., the temperature of the memory array 301, and the temperature of certain peripheral circuits 302). Some temperature sensors 520 can sense the temperature of one or more parts of the memory controller 106 (e.g., the temperature of a front-end interface of the memory controller 106, the temperature of a flash translation layer (FTL) of the memory controller 106, and the temperature of the back-end interface of the memory controller 106). The temperature sensors 520 can sense temperature periodically, for example, once every 0.5 to 2 seconds. In some implementations, the temperature sensors 520 can sense temperature aperiodically, from time to time, or on demand. The temperature sensors 520 sends the sensed temperature to the memory controller 106.

In some implementations, the memory controller 106 can include a temperature sampling circuit 502. The temperature sampling circuit 502 can receive the temperatures sensed by the temperature sensors 520, and determine a system temperature that represents a current temperature of the memory system (e.g., the memory system 100 of FIG. 1). For example, the system temperature can be an average, a weighted average, or another temperature fitted based on some or all of the temperatures received from the temperature sensors 520. The temperature sampling circuit 502 may apply other algorithms to determine the system temperature based on temperatures received from the temperature sensors 520. In some implementations, the system temperature is included as the current temperature in the Self-Monitoring, Analysis and Reporting Technology (SMART) information of the memory system. The SMART information can report various indicators (e.g., current temperature, power cycles, power-on hours, media errors) that may have impact on the reliability of the memory system to a user. As such, the user can predict potential failures based on the SMART information, and can take actions to prevent data loss.

In some implementations, the memory controller 106 is configured to control the temperature of the memory system, for example, to prevent overheating. For example, the memory controller 106 can determine a delay based on the current temperature of the memory system, and control the memory device to hold off executing the next operation (e.g., a read operation, a write operation, or an erase operation) until the delay elapses. As such, the temperature of the memory system can be decreased, compared to scenarios where the memory device executes the next operation without the delay. In some implementations, the memory controller can implement fuzzy logic to determine the delay based on the current temperature of the memory system.

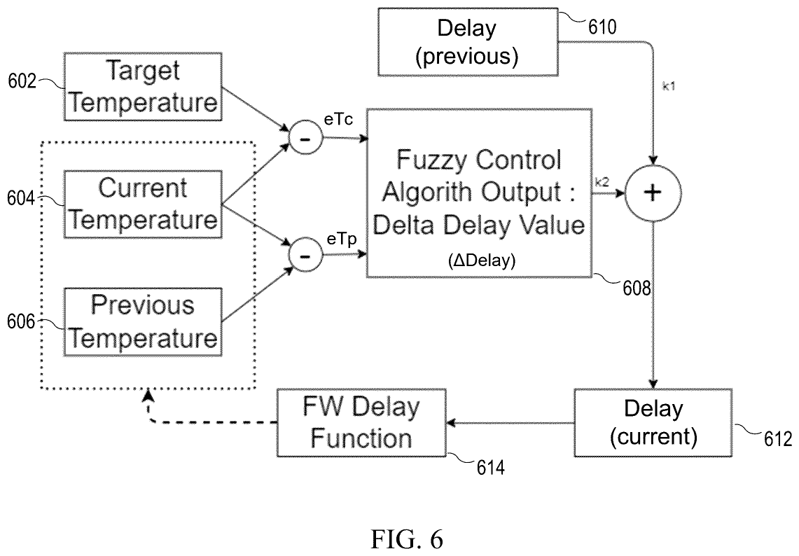

In some implementations, the memory controller 106 can include one or more processors. One processor of the memory controller 104 can include a delay adjusting circuit 504. The delay adjusting circuit 504 can determine the delay using fuzzy logic. With reference to FIG. 6, the delay adjusting circuit 504 can receive a first temperature difference (eTc) and a second temperature difference (eTp) as inputs. In some implementations, the first temperature difference (eTc) can be a difference between the current temperature 604 and a target temperature 602 of the memory system. The current temperature 604 can be the system temperature determined by the temperature sampling circuit 502. The target temperature can be the maximum value or another value in an expected temperature range (e.g., 10° C. to 80° C.) in which the memory system can properly operate. In some implementations, the target temperature can be used as a threshold temperature for thermal throttling. For example, when the current temperature of the memory system exceeds the target temperature, the memory system will activate its thermal throttling mechanism to reduce heat generation. In some implementations, the second temperature difference (eTp) can be a difference between the current temperature 604 and a previous temperature 606. The previous temperature 606 can be a system temperature determined by the temperature sampling circuit 502 in the last temperature sensing cycle or a previous reference point.

As shown in FIG. 5, the delay adjusting circuit 504 can include a fuzzification unit $12 that fuzzifies the first and second temperature differences, an inference engine 514 that makes inferences on a delay or a delay change (ΔDelay) 608 according to fuzzy rules 518, and a de-fuzzification unit 516 that outputs a crisp value for the delay change 608.

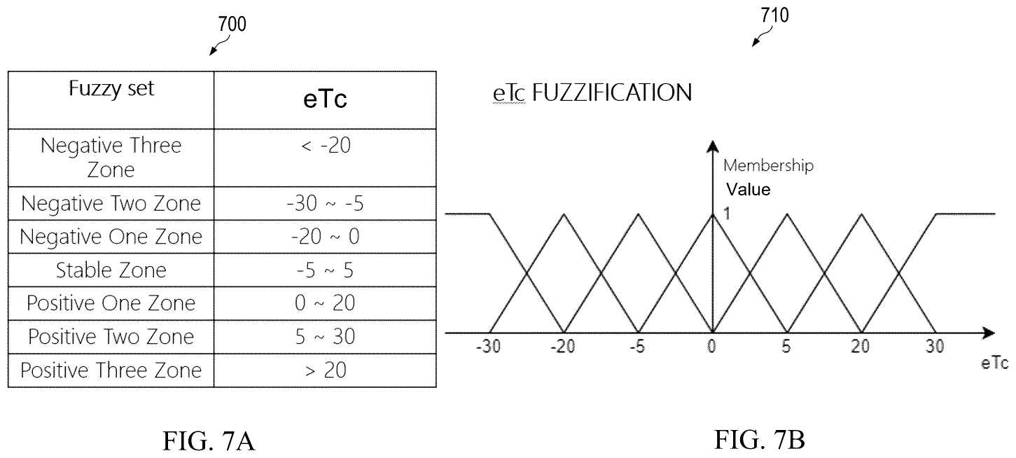

In some implementations, the fuzzification unit 512 can fuzzify the first temperature difference (eTc) into first fuzzy sets, and determine first membership values of eTc with respect to the first fuzzy sets. For example, the fuzzification unit 512 can fuzzify eTc using a mapping table and a membership function. With reference to FIG. 7A, the mapping table 700 shows the mapping relation between ranges of eTc and the first fuzzy sets. Since eTc in the mapping table 700 is based on in-situ values (e.g., raw data without unit) from the temperature sensors 520, in some cases, eTc can be converted to temperature in degree Celsius approximately as 1 eTc=0.3° C. As one example, according to the mapping table 700, if eTc is −25, it falls into negative three zone and negative two zone; if eTc is 5, it falls into stable zone, positive one zone, and positive two zone. With reference to FIG. 7B, the membership function 710 can be used to determine the first membership value of eTc with respect to each fuzzy set that it falls into. As one example, under a linear membership function, if eTc is −10, its membership value with respect to negative two zone is 0.4, its membership value with respect to negative one zone is 1. It should be noted that the mapping table 700 and the membership function 710 are for illustration purposes only. The fuzzification unit 512 can fuzzify the first temperature difference (eTc) into first fuzzy sets in a different manner (e.g., different mapping relations, different membership functions such as non-liner functions) from the examples shown in FIGS. 7A-7B.

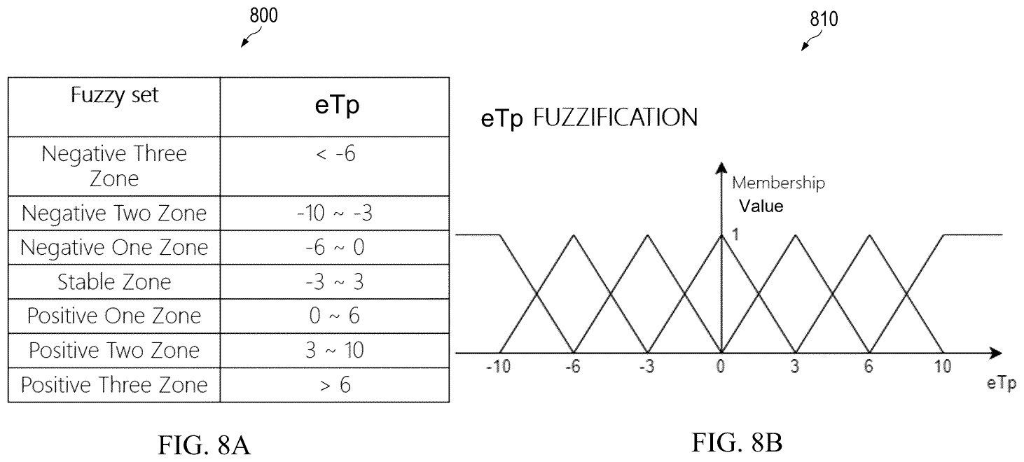

In some implementations, the fuzzification unit 512 can fuzzify the second temperature difference (eTp) into second fuzzy sets, and determine second membership values of eTp with respect to the second fuzzy sets. For example, the fuzzification unit 512 can fuzzify eTp using a mapping table and a membership function. With reference to FIG. 8A, the mapping table 800 shows the mapping relation between ranges of eTp and the second fuzzy sets. Since eTp in the mapping table 800 is based on in-situ values (e.g., raw data without unit) from the temperature sensors 520, in some cases, eTp can be converted to temperature in degree Celsius approximately as 1 eTp=0.3° C. As one example, according to the mapping table 800, if eTp is −10, it falls into negative three zone and negative two zone; if eTp is 5, it falls into positive one zone and positive two zone. With reference to FIG. 8B, the membership function 810 can be used to determine the second membership value of eTp with respect to each fuzzy set that it falls into. As one example, under a linear membership function, if eTp is 1, its membership value with respect to stable zone is ⅔, its membership value with respect to positive one zone is ⅓. It should be noted that the mapping table 800 and the membership function 810 are for illustration purposes only. The fuzzification unit 512 can fuzzify the second temperature difference (eTp) into second fuzzy sets in a different manner (e.g., different mapping relations, different membership functions such as non-liner functions) from the examples shown in FIGS. 8A-8B.

In some implementations, the inference engine 514 can make inferences on a delay change (ΔDelay) using fuzzy rules 518 based on the first fuzzy sets, first membership values, second fuzzy sets and the second membership values. The fuzzy rules 518 can define the calculative method of generating an output (e.g., ΔDelay) based on one or more inputs (e.g., eTc, eTp) into the inference engine 514. For example, the fuzzy rules 518 can include a mapping relationship (e.g., a look-up table) that can be used to infer third fuzzy sets that candidate delay changes falls into.

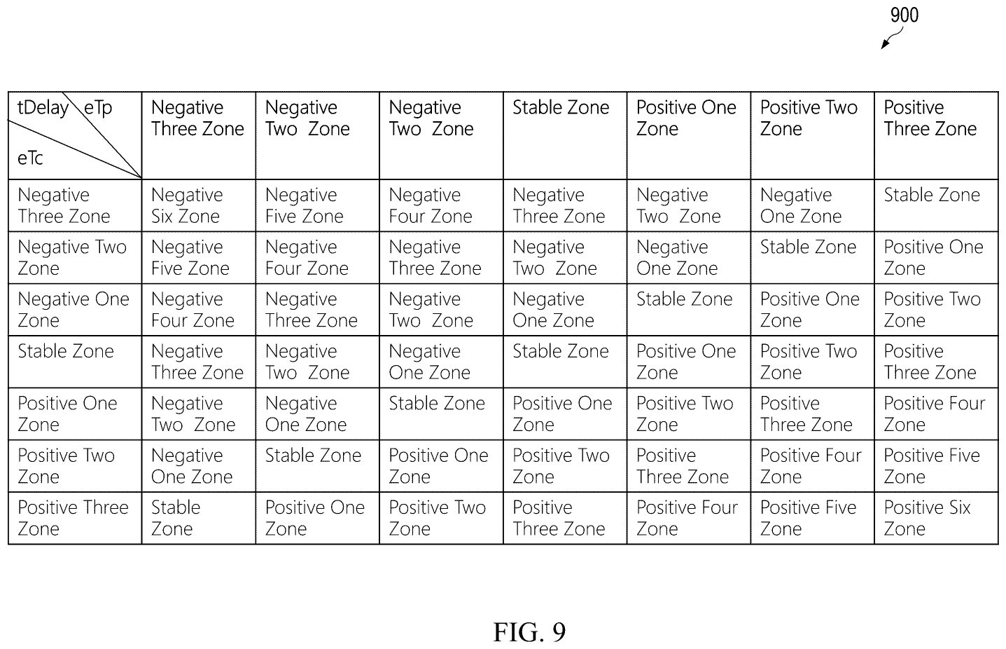

With reference to FIG. 9, the look-up table 900 can be used to determine the third fuzzy sets that candidate ΔDelay fall into, based on the first fuzzy sets that eTc falls into, and the second fuzzy sets that eTp falls into. In some implementations, the row number of a cell in the look-up table 900 stands for the first fuzzy set that the input eTc falls into, the column number of the cell stands for the second fuzzy set that the input eTp falls into, while the cell indicates a third fuzzy set that a candidate delay change falls into. As an example, if eTc is −10, which falls into negative two zone and negative one zone, and if eTp is 1, which falls into stable zone and positive one zone, then according to the look-up table 900, a first candidate ΔDelay falls into negative two zone, a second candidate ΔDelay and a third candidate ΔDelay fall into negative one zone, and a fourth candidate ΔDelay falls into stable zone.

In some implementations, the fuzzy rules 518 can include formula that determines third membership values of each candidate delay change with respect to the third fuzzy sets that the candidate falls into. For example, the third membership value of each candidate delay change with respect to the third fuzzy set can be determined as a smaller value of an associated first membership value and an associated second membership value, where the associated first membership value is the membership value of eTc with respect to a first fuzzy set associated with the third fuzzy set according to the look-up table 900, and the associated second membership value is the membership value of eTp with respect to a second fuzzy set associated with the third fuzzy set according to the look-up table 900. As an example, in the scenario where eTc falls into negative two zone (with membership value 0.4) and negative one zone (with membership value 1), and eTp falls into stable zone (with membership value ⅔) and positive one zone (with membership value ⅓), the membership value of the first candidate delay change with respect to negative two zone can be 0.4 (the smaller value of 0.4 and ⅔); the membership value of the second candidate delay change with respect to negative one zone can be ⅓ (the smaller value of 0.4 and ⅓); the membership value of the third candidate delay change with respect to negative one zone can be ⅔ (the smaller value of 1 and ⅔); and the membership value of the fourth candidate delay change with respect to stable zone can be ⅓ (the smaller value of 1 and ⅓). In some implementations, the third membership values of candidate delay changes can be determined based on other formulas. For example, the third membership value of a candidate delay change can be determined as a larger value, an average value, or a weighted average value of an associated first membership value and an associated second membership value.

In some implementations, the de-fuzzification unit 516 can output a target delay change (e.g., a crisp value for the delay change 608) based on the candidate delay changes, their respective third fuzzy sets, and their respective membership value. For example, the target delay change (ΔDelay) can be calculated using a centroid method where: target ΔDelay=Σ₁ⁿ(Xi×μ(Xi))/Σ₁ⁿ(μ((Xi), where Xi is the maximum candidate delay change that could fall in a third fuzzy set, u (Xi) is the membership value of a candidate delay change with respect to the third fuzzy set.

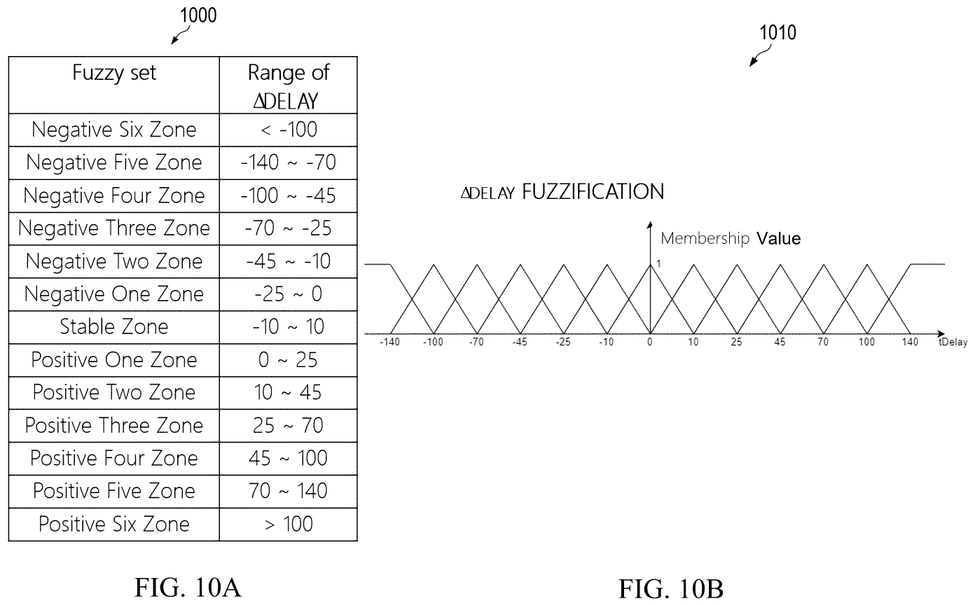

With reference to FIG. 10A, a mapping table 1000 shows the mapping relation between ranges of candidate ΔDelay and the third fuzzy sets. As an example, if the first candidate delay falls into negative two zone (with membership value 0.4), the second candidate delay falls into negative one zone (with membership value ⅓), the third candidate delay falls into negative one zone (with membership value ⅔), and the fourth candidate delay change falls into stable zone (with membership value of ⅓), then the target ΔDelay=(−45)×0.4+(−25)×⅓+(−25)×⅔+10×½/0.4+⅓+⅔+⅓=−22.89. In some other implementations, the target delay change can be calculated from the candidate delay changes based on other formulas or other function plots, such as the membership function 1010 of FIG. 10B, which indicates ΔDelay based on membership value with respect to each of the third fuzzy sets.

Referring back to FIGS. 5-6, after obtaining the target delay change 608, a delay 612 of the current cycle can be calculated by adding the target delay change 608 to a previous delay 610 determined by the delay adjusting circuit 504 in a previous cycle. A cycle can be defined as a time period when the delay adjusting circuit 504 adjusts the delay 612 once. In some implementations, the delay 612 can be stored in a storage medium (e.g., a register) of the memory controller 106. One or more processors of the memory controller 106 can read the delay 612 from the storage medium to control the memory device 104 to execute an operation (e.g., a read operation, a write operation, or an erase operation) after the delay.

In some implementations, one or more processors of the memory controller 106 can include a delay execution circuit 506. In response to receiving the delay 612, the delay execution circuit 506 can implement delay functions 614 by instructing the processors of the memory controller 106 to execute a number of No-Operation (NOP) commands before sending the next operation command (e.g., a read command, a write command, or an erase command) to the memory device 104. In some implementations, the number of NOP commands that the processors execute is correlated with (e.g., in direct proportion to) the delay 612. As such, the memory device 104 can hold off executing the next operation until after the delay 612, so as to decrease the temperature of the memory system. It should be noted that the memory controller 106 can be configured to control the temperature of the memory system according to the delay by means other than executing NOP command, for example, by increasing the power of the cooling system of the memory device 104, or by reducing the CPU frequency of the control logic (e.g., control logic 412 of FIG. 4) of the memory device 104.

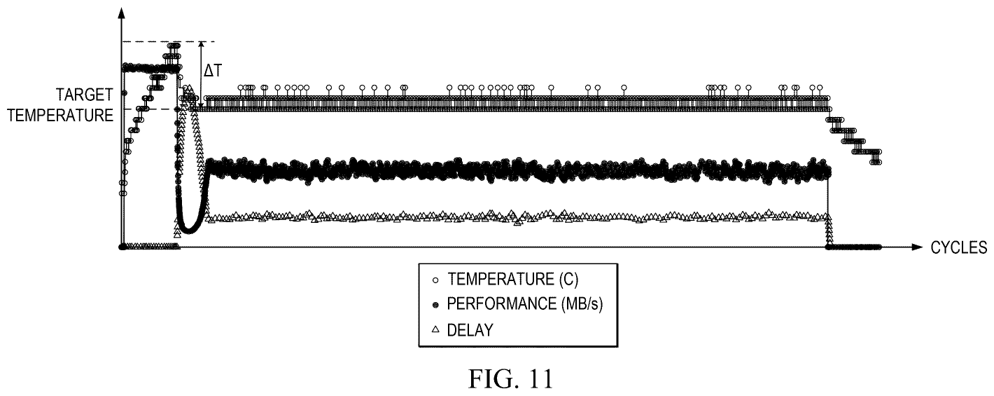

FIG. 11 illustrates performances of a memory system where temperature is controlled using a Proportional-Integral-Derivative (PID) mechanism to calculate the delay based on the current temperature of the memory system. The PID mechanism adjusts the delay in consideration of (1) a temperature error between the current temperature and a target temperature or a previous temperature, (2) a cumulative temperature error that sums the temperature errors over time, and (3) a current rate of change of temperature error. As shown in FIG. 11, when temperature is controlled using the PID mechanism, especially in early cycles (e.g., during the first 1000 cycles), temperature of the memory system may rise rapidly with issues of temperature overshooting. Temperature overshooting means that the temperature of the memory system may rise to a higher value than the target value, such that the difference (ΔT) between the higher value and the target value is larger than a threshold (e.g., 2° C.). For example, as shown in FIG. 11, the difference (ΔT) between the highest value of the temperature (e.g., system temperature) of the memory system and the target temperature can be greater than the threshold. In response to temperature overshooting, the memory controller adds long delays before operations of the memory device, so that the performance (e.g., operating speed) of the memory system drops significantly in a short period of time, which may negative affect the efficiency of the memory system.

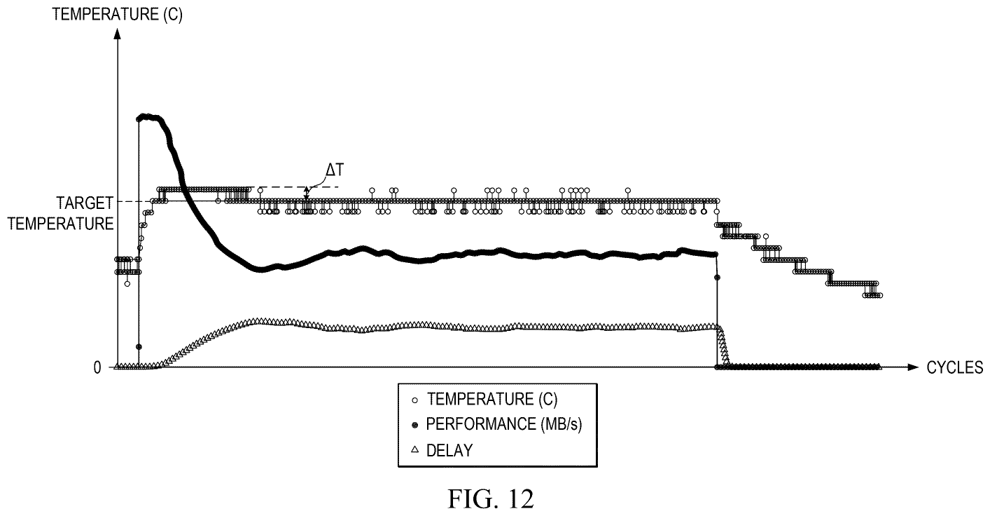

FIG. 12 illustrates performances of a memory system where temperature is controlled using fuzzy logic, according to some aspects of the present disclosure. In some implementations, the memory system applies fuzzy logic to calculate the delay based on the current temperature of the memory system, according to the example techniques described with respect to FIGS. 5-10. As shown in FIG. 12, the temperature of memory system increases gradually to the target temperature, and then stabilizes around the target temperature. Temperature control using fuzzy logic can mitigate the issue of temperature overshooting. In some implementations, from the beginning cycle towards late cycles, the difference (ΔT) between the temperature of the memory system (e.g., system temperature) and the target temperature can be kept under the threshold (e.g., 2° C.). For example, as shown in FIG. 12, by implementing temperature control using fuzzy logic, the difference (ΔT) between the highest value of the temperature of the memory system and the target temperature can be less than 2° C. During the period where the temperature gradually increases to the target temperature, the memory controller slowly increases the length of the delay, so that the performance of the memory system are more stable, compared to FIG. 11.

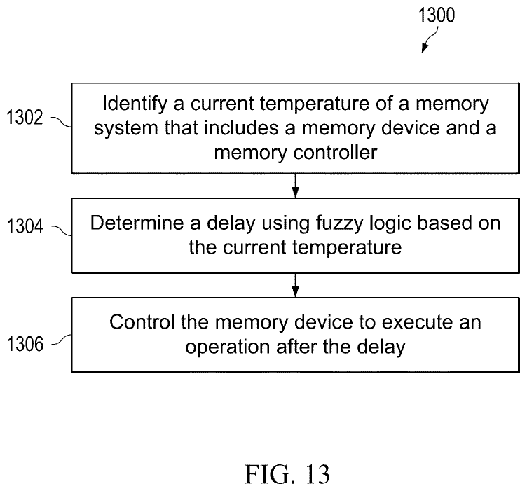

FIG. 13 illustrates a flow chart of an example method 1300 of operating a memory system, according to some aspects of the present disclosure. Method 1300 can be performed by any suitable device or system as described herein, for example, according to the example techniques described with respect to FIGS. 1-12. For example, method 1300 can be performed by a memory controller, such as the memory controller 106 of FIG. 5 that includes a temperature sampling circuit 502, a delay adjusting circuit 504, and a delay execution circuit 506. The memory device can be a part of a memory system, such as memory system 102 of FIG. 1.

The operations shown in method 1300 may not be exhaustive and that other operations can be performed as well before, after, or in between any of the illustrated operations. Further, some of the operations may be performed simultaneously, or in a different order than shown in FIG. 13. In some implementations, some of the operations may be performed by or one or more components of a device or a system, such as, a peripheral circuit of the memory device.

At 1302, the memory controller identifies a current temperature of the memory system. In some implementations, temperature sensors (e.g., temperature sensors 520) can be positioned on one or more parts of the memory device and the memory controller. The temperature sampling circuit of the memory controller can receive temperature sensed by temperature sensors, and determine a system temperature that represents a current temperature of the memory system. For example, the memory controller is configured to identify the current temperature of the memory system by operations comprising receiving a first temperature from a first sensor positioned in the memory device; receiving a second temperature from a second sensor positioned in the memory controller; and determining the current temperature of the memory system based on at least one of the first temperature or the second temperature. In some implementations, the current temperature is determined as a weighted average or another function of the first temperature and the second temperature.

At 1304, the memory controller determines a delay using fuzzy logic based on the current temperature, for example, according to the example techniques described with respect to FIGS. 6-10. In some implementations, the delay adjusting circuit of the memory controller can receive two inputs, and generate the delay as output using fuzzy logic. In some implementations, the first input can be a first temperature difference (eTc) between the current temperature (e.g., current temperature 604 of FIG. 6) and a target temperature (e.g., target temperature 602 of FIG. 6). The first input can be fuzzified into first fuzzy sets that eTc falls into (e.g., according to mapping table 700 of FIG. 7A) and first membership values with respect to the first fuzzy sets (e.g., according to membership function 710 of FIG. 7B).

In some implementations, the second input can be a second temperature difference (eTp) between the current temperature and a previous temperature (e.g., previous temperature 606 of FIG. 6). In some implementations, the second input can be fuzzified into second fuzzy sets that eTp falls into (e.g., according to mapping table 800 of FIG. 8A) and second membership values with respect to the second fuzzy sets (e.g., according to membership function 810 of FIG. 8B).

In some implementations, the delay adjusting circuit can infer on a delay change (e.g., delay change 608 of FIG. 6) using fuzzy rules (e.g., fuzzy rules 518 of FIG. 5). Based on the first fuzzy sets, first membership values, second fuzzy sets and the second membership values, the delay adjusting circuit can determine the third fuzzy sets that candidate delay changes fall into (e.g., according to look-up table 900 of FIG. 9) and the third membership values with respect to third fuzzy sets. For example, the first fuzzy sets and the second fuzzy sets can be mapped into the third fuzzy sets that indicate candidate delay changes, for example, according to the look-up table 900 of FIG. 9. The third membership values of the candidate delay changes with respect to third fuzzy sets are determined based on the first membership values and the second membership values. For example, the third membership value of a candidate delay change can be a smaller value, a larger of value, an average, or a weighted average of an associated first membership value and an associated second membership value.

The delay adjusting circuit can determine a target delay change by de-fuzzifying the candidate delay changes (e.g., according to the mapping table 1000 of FIG. 10A and/or the membership function 1010 of FIG. 10B) For example, the target delay change can be determined based on the candidate delay changed indicated by the third fuzzy sets and the third membership values of the candidate delay change with respect to the third fuzzy sets. A delay (e.g., delay 612 of FIG. 6) of the current cycle can be calculated by adding the target delay change to a previous delay (e.g., previous delay 610 of FIG. 6) determined in a previous cycle or a previous reference point. That is, the delay is a sum of the previous delay determined by the memory controller and the target delay change.

At 1306, the memory controller controls the memory device to execute an operation (e.g., a read operation, a write operation, or an erase operation) after the delay. In some implementations, the delay can be represented or implemented as a number of NOP commands. For example, one or more processors of the memory controller can execute a number of NOP commands before sending the next command (e.g., e.g., a read command, a write command, or an erase command) to the memory device, so that the next operation of the memory device is delayed. In some implementations, the number of NOP commands is correlated with (e.g., in positive proportion to) the delay. The larger the number of NOP commands is, the longer the delay is. In some implementations, the delay can be implemented by lowing a frequency of one or more processors of the memory controller so as to lower the temperature of the memory system. Additional or different techniques can be used to implement the delay to manage the temperature of the memory system.

The present disclosure also provides a non-transitory computer-readable storage medium. The non-transitory computer-readable storage medium stores one or more instructions (e.g., firmware of a memory controller) that are executable by a computer system. When being executed by the computer system, the instructions in the storage medium can implement method for managing temperature in a memory system as shown in FIGS. 5-10 and FIGS. 12-13.

The non-transitory computer-readable storage medium can be an internal storage unit of the device described in any of the foregoing embodiments. For example, the non-transitory computer-readable storage medium can be a hard disk or an internal memory of the device. The non-transitory computer-readable storage medium can also be an external storage device of the device, such as a plug-in hard disk, a smart media card (SMC), a secure digital (SD) card, a flash card, etc. Further, the non-transitory computer-readable storage medium can also include an internal storage unit and the external storage device.

While this specification contains many specific implementation details, these should not be construed as limitations on the scope of what may be claimed, but rather as descriptions of features that may be specific to particular implementations. Certain features that are described in this specification in the context of separate implementations can also be implemented, in combination, in a single implementation. Conversely, various features that are described in the context of a single implementation can also be implemented in multiple implementations, separately, or in any sub-combination. Moreover, although previously described features may be described as acting in certain combinations and even initially claimed as such, one or more features from a claimed combination can, in some cases, be excised from the combination, and the claimed combination may be directed to a sub-combination or variation of a sub-combination.

As used in this disclosure, the terms “a,” “an,” or “the” are used to include one or more than one unless the context clearly dictates otherwise. The term “or” is used to refer to a nonexclusive “or” unless otherwise indicated. The statement “at least one of A and B” has the same meaning as “A, B, or A and B.” In addition, the phraseology or terminology employed in this disclosure, and not otherwise defined, is for the purpose of description only and not of limitation. Any use of section headings is intended to aid reading of the document and is not to be interpreted as limiting; information that is relevant to a section heading may occur within or outside of that particular section.

As used in this disclosure, the term “about” or “approximately” can allow for a degree of variability in a value or range, for example, within 10%, within 5%, or within 1% of a stated value or of a stated limit of a range.

As used in this disclosure, the term “substantially” refers to a majority of, or mostly, as in at least about 50%, 60%, 70%, 80%, 90%, 95%, 96%, 97%, 98%, 99%, 99.5%, 99.9%, 99.99%, or at least about 99.999% or more.

Values expressed in a range format should be interpreted in a flexible manner to include not only the numerical values explicitly recited as the limits of the range, but also to include all the individual numerical values or sub-ranges encompassed within that range as if each numerical value and sub-range is explicitly recited. For example, a range of “0.1% to about 5%” or “0.1% to 5%” should be interpreted to include about 0.1% to about 5%, as well as the individual values (for example, 1%, 2%, 3%, and 4%) and the sub-ranges (for example, 0.1% to 0.5%, 1.1% to 2.2%, 3.3% to 4.4%) within the indicated range. The statement “X to Y” has the same meaning as “about X to about Y,” unless indicated otherwise. Likewise, the statement “X, Y, or Z” has the same meaning as “about X, about Y, or about Z,” unless indicated otherwise.

Particular implementations of the subject matter have been described. Other implementations, alterations, and permutations of the described implementations are within the scope of the following claims as will be apparent to those skilled in the art. While operations are depicted in the drawings or claims in a particular order, such operations are not required be performed in the particular order shown or in sequential order, or that all illustrated operations be performed (some operations may be considered optional), to achieve desirable results. In certain circumstances, multitasking or parallel processing (or a combination of multitasking and parallel processing) may be advantageous and performed as deemed appropriate.

Moreover, the separation or integration of various system modules and components in the previously described implementations are not required in all implementations, and the described components and systems can generally be integrated together or packaged into multiple products.

Accordingly, the previously described example implementations do not define or constrain the present disclosure. Other changes, substitutions, and alterations are also possible without departing from the spirit and scope of the present disclosure.

What is claimed is:

1. A memory system, comprising:
a memory device comprising memory cells; and
a memory controller coupled to the memory device and configured to:
identify a current temperature of the memory system;
determine a delay using fuzzy logic based on the current temperature; and
control the memory device to execute an operation after the delay.

2. The memory system of claim 1, wherein the memory controller is configured to identify the current temperature of the memory system by operations comprising:
receiving a first temperature from a first sensor positioned in the memory device;
receiving a second temperature from a second sensor positioned in the memory controller; and
determining the current temperature of the memory system based on at least one of the first temperature or the second temperature.

3. The memory system of claim 2, wherein the current temperature is determined as a weighted average of the first temperature and the second temperature.

4. The memory system of claim 2, wherein the memory controller receives the first temperature and the second temperature periodically.

5. The memory system of claim 1, wherein the memory controller is configured to determine the delay using fuzzy logic by operations comprising:
fuzzifying a first difference between the current temperature and a previous temperature of the memory system into first membership values of the first difference with respect to first fuzzy sets that the first difference falls into;
fuzzifying a second difference between the current temperature and a target temperature into second membership values of the second difference with respect to second fuzzy sets that the second difference falls into;
mapping the first fuzzy sets and the second fuzzy sets into third fuzzy sets that indicate candidate delay changes,
determining third membership values of the candidate delay changes with respect to third fuzzy sets based on the first membership values and the second membership values; and
determining a target delay change by de-fuzzifying the candidate delay changes, wherein the delay is a sum of a previous delay determined by the memory controller and the target delay change.

6. The memory system of claim 5, wherein determining the target delay change by de-fuzzifying the candidate delay changes comprises:
determining the target delay change based on the candidate delay changes indicated by the third fuzzy sets and the third membership values of the candidate delay changes with respect to the third fuzzy sets.

7. The memory system of claim 5, wherein the second difference is less than 2 degree Celsius.

8. The memory system of claim 1, wherein the operation comprises one of a read operation, a write operation or an erase operation.

9. The memory system of claim 1, wherein the memory controller is configured to control the memory device to execute the operation after the delay by operations comprising:
executing, by a processor of the memory controller, one or more No-Operation (NOP) commands, wherein a quantity of the NOP commands is correlated with the delay.

10. The memory system of claim 1, wherein the delay is stored in a storage medium of the memory controller, and a processor of the memory controller is configured to read the delay from the storage medium to control the memory device to execute the operation after the delay.

11. A memory controller, comprising:
a temperature sampling circuit configured to identify a current temperature of a memory system comprising a memory device and the memory controller;
a first processor configured to determine a delay using fuzzy logic based on the current temperature; and
a second processor configured to control a memory device to execute an operation after the delay.

12. The memory controller of claim 11, wherein the temperature sampling circuit is configured to identify the current temperature of the memory system by operations comprising:
receiving a first temperature from a first sensor positioned in the memory device;
receiving a second temperature from a second sensor positioned in the memory controller; and
determining the current temperature of the memory system based on at least one of the first temperature or the second temperature.

13. The memory controller of claim 11, wherein the first processor is configured to determine the delay using fuzzy logic by operations comprising:
fuzzifying a first difference between the current temperature and a previous temperature of the memory system into first membership values of the first difference with respect to first fuzzy sets that the first difference falls into;
fuzzifying a second difference between the current temperature and a target temperature into second membership values of the second difference with respect to second fuzzy sets that the second difference falls into;
mapping the first fuzzy sets and the second fuzzy sets into third fuzzy sets that indicate candidate delay changes;
determining third membership values of the candidate delay changes with respect to third fuzzy sets based on the first membership values and the second membership values; and
determining a target delay change by de-fuzzifying the candidate delay changes, wherein the delay is a sum of a previous delay determined by the memory controller and the target delay change.

14. The memory controller of claim 13, wherein determining the target delay change by de-fuzzifying the candidate delay changes comprises:
determining the target delay change based on the candidate delay changes indicated by the third fuzzy sets and the third membership values of the candidate delay changes with respect to third fuzzy sets.

15. The memory controller of claim 11, wherein the second processor is configured to control the memory device to execute the operation after the delay by operations comprising:
executing, by a processor of the memory controller, one or more No-Operation (NOP) commands, wherein a quantity of the NOP commands is correlated with the delay.

16. The memory controller of claim 11, wherein the delay is stored in a storage medium of the memory controller, and the second processor is configured to read the delay from the storage medium to control the memory device to execute the operation after the delay.

17. A method of operating a memory system, comprising:
identifying a current temperature of the memory system comprising a memory controller and a memory device;
determining a delay using fuzzy logic based on the current temperature; and
controlling the memory device to execute an operation after the delay.

18. The method of claim 17, wherein determining the delay using fuzzy logic by operations comprises:
fuzzifying a first difference between the current temperature and a previous temperature of the memory system into first membership values of the first difference with respect to first fuzzy sets that the first difference falls into;
fuzzifying a second difference between the current temperature and a target temperature into second membership values of the second difference with respect to second fuzzy sets that the second difference falls into;
mapping the first fuzzy sets and the second fuzzy sets into third fuzzy sets that indicate candidate delay changes;
determining third membership values of the candidate delay changes with respect to third fuzzy sets based on the first membership values and the second membership values; and
determining a target delay change by de-fuzzifying the candidate delay changes, wherein the delay is a sum of a previous delay determined by the memory controller and the target delay change.

19. The method of claim 17, wherein controlling the memory device to execute the operation after the delay comprises:
executing, by a processor of the memory controller, one or more No-Operation (NOP) commands, wherein a quantity of the NOP commands is correlated with the delay.

20. The method of claim 17, comprising:
storing the delay in a storage medium of the memory controller; and
reading, by a processor of the memory controller, the delay from the storage medium to control the memory device to execute the operation after the delay.
